(19) United States
(12) Patent Application Publication
(10) Pub. No.: US 2009/0302347 A1
(43) Pub. Date: Dec. 10, 2009

(54) Semiconductor integrated circuit

(76) Inventors: Hiroki Matsunaga, Osaka (JP); Masahiko Sasada, Kyoto (JP); Akihiro Maejima, Osaka (JP); Jinsaku Kaneda, Osaka (JP); Hiroshi Ando, Osaka (JP)

Correspondence Address: MCDERMOTT WILL & EMERY LLP, 600 13TH STREET, NW, WASHINGTON, DC, 20005-3096, US

(21) Appl. No.: 11/919,504

(22) PCT Filed: Sep. 29, 2006
(86) PCT No.: PCT/JP2006/319533

§ 371 Date: Oct. 29, 2007

(30) Foreign Application Priority Data
Mar. 6, 2006 (JP) 2006-059112

(51) Int. Cl. H01L 27/04; H01L 29/861

(52) U.S. Cl. 257/146; 257/173; 257/E27.011; 257/168; 257/E29.327; 361/56

(57) ABSTRACT

A semiconductor integrated circuit includes a plurality of circuit cells each including a pad on a semiconductor chip. Each of the circuit cells includes a high-side transistor, a level shift circuit, a low-side transistor, a pre-driver, and a pad. The high-side transistor and the low-side transistor are arranged to face each other with the pad interposed therebetween.

### TECHNICAL FIELD

The present invention relates to a semiconductor integrated circuit. Specifically, the present invention relates to a layout of a multi-channel semiconductor integrated circuit which drives a capacitive load such as a plasma display.

### BACKGROUND ART

Generally, a known example of an output circuit used for a multi-channel semiconductor integrated circuit is a MOS output circuit, an IGBT output circuit, a high-sideless MOS output circuit, or a high-sideless IGBT output circuit. Usually, cells of the output circuit mentioned above are laid out as standard cells in the multi-channel semiconductor integrated circuit. For example, in a standard cell 116 constituting an output circuit which includes a MOS driver, as shown in FIG. 13A and FIG. 13B, a pad 108 is arranged at the bottom (lower side in the drawings); and a low-side transistor 111, a high-side transistor 110, a level shift circuit 112, and a pre-driver 113 are arranged over the pad 108 in this order from the bottom to the top (upper side in the drawings). In this case, each of the components (111, 110, 112, 113) of the standard cell 116 is electrically connected to the pad 108 via a two-layer line 114 or a one-layer line 115 (with regard to the above-mentioned layout, see Patent Document 1, for example). In FIG. 13B, a drain region 119 of the high-side transistor, a source region 120 of the high-side transistor, through holes 121, a drain region 122 of the low-side transistor, and a source region 123 of the low-side transistor are shown.

Patent Document 1: Japanese Laid-Open Patent Publication No. 1-18239

### DISCLOSURE OF INVENTION

### Problems to be Solved by the Invention

However, as described with reference to FIG. 13A and FIG. 13B, when a surge voltage or the like is applied to the pad 108, surge charges concentrate on a body diode of the low-side transistor 111 although it is attempted to prevent an electrostatic breakdown by releasing the surge charges in a forward direction of a body diode (not shown) of the high-side transistor 110 connected on a power source side. The reason why is that the line impedance of the low-side transistor 111 arranged adjacently to the pad 108 is greatly lower than that of the body diode of the high-side transistor 110 arranged apart from the pad 108. Therefore, there is a problem that the body diode of the low-side transistor 111 may first break down.

Such a problem occurs not only in the output circuit including the MOS driver but also in an output circuit including the IGBT driver, the high-sideless MOS driver, or the high-sideless IGBT driver mentioned above.

In view of the above-mentioned problems, an object of the present invention is to provide a semiconductor integrated circuit which has a layout highly resistive against the electrostatic breakdown.

### Means for Solving the Problems

To achieve the above-mentioned object, a semiconductor integrated circuit of a first aspect of the present invention includes a plurality of circuit cells each having a pad on a semiconductor chip, each of the circuit cells including: a high breakdown voltage driver composed of a high-side transistor, a level shift circuit driving the high-side transistor, and a low-side transistor; a pre-driver driving the high breakdown voltage driver; and the pad, wherein the high-side transistor and the low-side transistor are arranged to face each other with the pad interposed therebetween.

In the semiconductor integrated circuit of the first aspect of the present invention, it is preferable that the high-side transistor, the pad, the low-side transistor, the level shift circuit, and the pre-driver are arranged in alignment with each other along a straight line.

The semiconductor integrated circuit of the first aspect of the present invention further includes: a control portion arranged in a center section of the semiconductor chip; a first circuit cell alignment of the plurality of circuit cells; and a second circuit cell alignment of the plurality of circuit cells, wherein the first circuit cell alignment and the second cell alignment face each other with the control portion interposed therebetween.

The semiconductor integrated circuit of the first aspect of the present invention further includes: first power source pads for a high voltage potential arranged on both ends of each of the first circuit cell alignment and the second circuit cell alignment; second power source pads for a reference potential arranged on both ends of each of the first circuit cell alignment and the second circuit cell alignment; first lines to which the high voltage potential is applied, each of the first lines being electrically connected to the first power source pads and being arranged over the high-side transistors in each of the first circuit cell alignment and the second circuit cell alignment; second lines to which the reference voltage is applied, each of the second line being electrically connected to the second power source pads and being arranged over the low-side transistors in each of the first circuit cell alignment and the second circuit cell alignment.

The semiconductor integrated circuit of the first aspect of the present invention further includes a third line to which the reference voltage is applied, the third line surrounding part of the control portion arranged in the center section of the semiconductor chip.

In the semiconductor integrated circuit of the first aspect of the present invention, the cell width of each of the level shift circuit and the pre-driver is smaller than or equal to that of the low-side transistor.

A semiconductor integrated circuit of a second aspect of the present invention includes a plurality of circuit cells each having a pad on a semiconductor chip, each of the circuit cells including: a high breakdown voltage driver composed of a high-side transistor, a level shift circuit driving the high-side transistor, a high-side regenerative diode, a low-side transistor, and a low-side regenerative diode; a pre-driver driving the high breakdown voltage driver; and the pad, wherein the high-side regenerative diode and the low-side regenerative diode are arranged to face each other with the pad interposed therebetween.

In the semiconductor integrated circuit of the second aspect of the present invention, it is preferable that the high-side regenerative diode, the pad, the low-side regenerative diode, the low-side transistor, the high-side transistor, the level shift circuit, and the pre-driver are arranged in alignment with each other along a straight line.

The semiconductor integrated circuit of the second aspect of the present invention further includes: a control portion arranged in a center section of the semiconductor chip; a first circuit cell alignment of the plurality of circuit cells; and a second circuit cell alignment of the plurality of circuit cells, wherein the first circuit cell alignment and the second cell alignment face each other with the control portion interposed therebetween.

The semiconductor integrated circuit of the second aspect of the present invention further includes: first power source pads for a high voltage potential arranged on both ends of each of the first circuit cell alignment and the second circuit cell alignment; second power source pads for a reference potential arranged on both ends of each of the first circuit cell alignment and the second circuit cell alignment; first lines to which the high voltage potential is applied, each of the first lines being electrically connected to the first power source pads and being arranged over the high-side regenerative diodes in each of the first circuit cell alignment and the second circuit cell alignment; second lines to which the reference voltage is applied, each of the second line being electrically connected to the second power source pads and being arranged over the low-side transistors in each of the first circuit cell alignment and the second circuit cell alignment.

The semiconductor integrated circuit of the second aspect of the present invention further includes a third line to which the reference voltage is applied, the third line surrounding part of the control portion arranged in the center section of the semiconductor chip.

In the semiconductor integrated circuit of the second aspect of the present invention, the cell width of each of the level shift circuit and the pre-driver is smaller than or equal to that of the low-side transistor.

A semiconductor integrated circuit of a third aspect of the present invention includes a plurality of circuit cells each having a pad on a semiconductor chip, each of the circuit cells including: a high breakdown voltage driver composed of an ESD protection element and a low-side transistor; a pre-driver driving the high breakdown voltage driver; and the pad, wherein the ESD protection element and the low-side transistor are arranged to face each other with the pad interposed therebetween.

In the semiconductor integrated circuit of the third aspect of the present invention, it is preferable that the ESD protection element, the pad, the low-side transistor, and the pre-driver are arranged in alignment with each other along a straight line.

The semiconductor integrated circuit of the third aspect of the present invention further includes: a control portion arranged in a center section of the semiconductor chip; a first circuit cell alignment of the plurality of circuit cells; and a second circuit cell alignment of the plurality of circuit cells, wherein the first circuit cell alignment and the second cell alignment face each other with the control portion interposed therebetween.

The semiconductor integrated circuit of the third aspect of the present invention further includes: first power source pads for a high voltage potential arranged on both ends of each of the first circuit cell alignment and the second circuit cell alignment; second power source pads for a reference potential arranged on both ends of each of the first circuit cell alignment and the second circuit cell alignment; first lines to which the high voltage potential is applied, each of the first lines being electrically connected to the first power source pads and being arranged over the ESD protection elements in each of the first circuit cell alignment and the second circuit cell alignment; second lines to which the reference voltage is applied, each of the second line being electrically connected to the second power source pads and being arranged over the low-side transistors in each of the first circuit cell alignment and the second circuit cell alignment.

The semiconductor integrated circuit of the third aspect of the present invention further includes a third line to which the reference voltage is applied, the third line surrounding part of the control portion arranged in the center section of the semiconductor chip.

In the semiconductor integrated circuit of the third aspect of the present invention, the cell width of each of the level shift circuit and the pre-driver is smaller than or equal to that of the low-side transistor.

A semiconductor integrated circuit of a fourth aspect of the present invention includes a plurality of circuit cells each having a pad on a semiconductor chip, each of the circuit cells including: a high breakdown voltage driver composed of an ESD protection element, a low-side regenerative diode, and a low-side transistor; a pre-driver driving the high breakdown voltage driver; and the pad, wherein the ESD protection element and the low-side regenerative diode are arranged to face each other with the pad interposed therebetween.

In the semiconductor integrated circuit of the fourth aspect of the present invention, it is preferable that the ESD protection element, the pad, the low-side regenerative diode, the low-side transistor, and the pre-driver are arranged in alignment with each other along a straight line.

The semiconductor integrated circuit of the fourth aspect of the present invention further includes: a control portion arranged in a center section of the semiconductor chip; a first circuit cell alignment of the plurality of circuit cells; and a second circuit cell alignment of the plurality of circuit cells, wherein the first circuit cell alignment and the second cell alignment face each other with the control portion interposed therebetween.

The semiconductor integrated circuit of the fourth aspect of the present invention further includes: first power source pads for a high voltage potential arranged on both ends of each of the first circuit cell alignment and the second circuit cell alignment; second power source pads for a reference potential arranged on both ends of each of the first circuit cell alignment and the second circuit cell alignment; first lines to which the high voltage potential is applied, each of the first lines being electrically connected to the first power source pads and being arranged over the ESD protection elements in each of the first circuit cell alignment and the second circuit cell alignment; second lines to which the reference voltage is applied, each of the second line being electrically connected to the second power source pads and being arranged over the low-side transistors in each of the first circuit cell alignment and the second circuit cell alignment.

The semiconductor integrated circuit of the fourth aspect of the present invention further includes a third line to which the reference voltage is applied, the third line surrounding part of the control portion arranged in the center section of the semiconductor chip.

In the semiconductor integrated circuit of the fourth aspect of the present invention, the cell width of each of the level shift circuit and the pre-driver is smaller than or equal to that of the low-side transistor.

### EFFECTS OF THE INVENTION

According to a semiconductor integrated circuit of the present invention, it is possible to suppress an electrostatic breakdown which occurs when an abnormal input such as a surge voltage is applied to a pad constituting a circuit cell. Moreover, it is possible to reduce the chip size. Moreover, it is possible to shorten the length of bonding wires connecting a number of pads with the outer region of a chip.

### BRIEF DESCRIPTION OF DRAWINGS

FIG. 1 is a circuit diagram illustrating an exemplary configuration of an output circuit including a MOS driver which has a pad of Embodiment 1 of the present invention.

FIG. 2A and FIG. 2B are enlarged plan views of an output circuit cell of Embodiment 1 of the present invention.

FIG. 3 is a plan view illustrating a layout of a semiconductor integrated circuit of Embodiment 1 of the present invention.

FIG. 4 is a circuit diagram illustrating an exemplary configuration of an output circuit including an IGBT driver which has a pad of Embodiment 2 of the present invention.

FIG. 5A and FIG. 5B are enlarged plan views of an output circuit cell of Embodiment 2 of the present invention.

FIG. 6 is a plan view illustrating a layout of a semiconductor integrated circuit of Embodiment 2 of the present invention.

FIG. 7 is a circuit diagram illustrating an exemplary configuration of an output circuit including a high-sideless MOS driver which has a pad of Embodiment 3 of the present invention.

FIG. 8A and FIG. 8B are enlarged plan views of an output circuit cell of Embodiment 3 of the present invention.

FIG. 9 is a plan view illustrating a layout of a semiconductor integrated circuit of Embodiment 3 of the present invention.

FIG. 10 is a circuit diagram illustrating an exemplary circuit configuration of an output circuit including a high-sideless IGBT driver which has a pad of Embodiment 4 of the present invention.

FIG. 11A and FIG. 11B are enlarged plan views of an output circuit cell of Embodiment 4 of the present invention.

FIG. 12 is a plan view illustrating a layout of a semiconductor integrated circuit of Embodiment 4 of the present invention.

FIG. 13A and FIG. 13B are enlarged plan views illustrating a conventional output circuit cell.

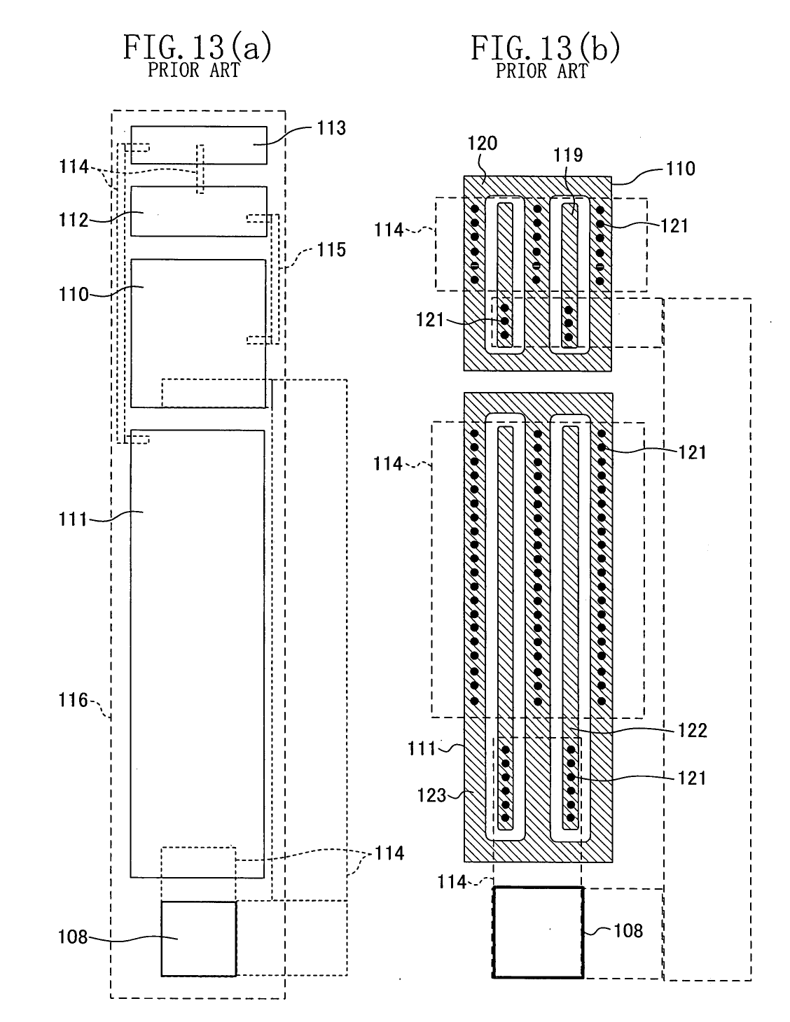

### DESCRIPTION OF REFERENCE NUMERALS

1 semiconductor chip
2, 2b line to which high voltage potential is applied
3a, 3b line to which reference potential is applied
4 pad for high voltage power source
5 pad for reference potential
6 low breakdown voltage control portion
7 bus line
8 pad
9 input control pad
10 high-side transistor
11 low-side transistor
12 level shift circuit
13 pre-driver
14 two-layer line
15 one-layer line
16a-16d output circuit cell
19 drain region of high transistor
20 source region of high-side transistor
21 through hole
22 drain region of low-side transistor
23 source region of low-side transistor
24 input terminal
25a-25d output circuit
26 parasitic diode between back gate and drain
27 parasitic diode between back gate and drain
28 high-side transistor
29 low-side transistor
30 high-side regenerative diode
31 low-side regenerative diode
32 diode for gate protection
33 gate-off resistor
34 gate protection circuit
35 high-side transistor emitter region
36 high-side transistor corrector region
37 low-side transistor emitter region
38 low-side transistor corrector region
39 diode cathode region
40 diode anode region
41 contact
43 ESD protection element
44 pre-driver
45 MOS driver
46 IGBT driver
47 high-sideless MOS driver
48 high-sideless IGBT driver

### BEST MODE FOR CARRYING OUT THE INVENTION

Embodiments of the present invention will be described below with reference to the drawings.

### Embodiment 1

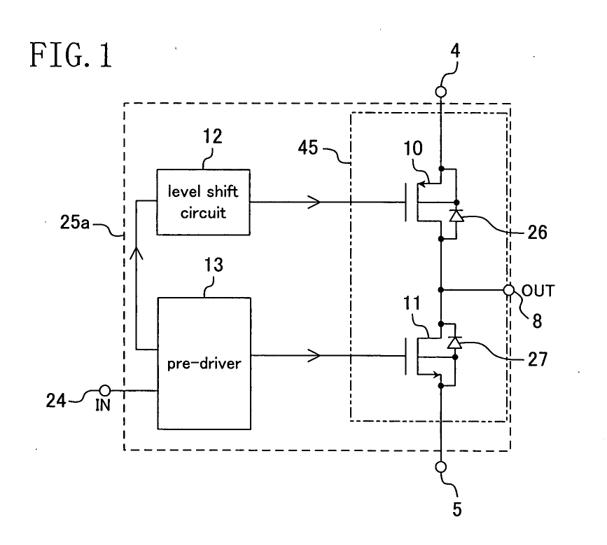

FIG. 1 is a circuit diagram illustrating a basic configuration of an output circuit 25a including an output circuit cell of a multi-channel semiconductor integrated circuit of Embodiment 1 of the present invention.

As shown in FIG. 1, the output circuit 25a includes a MOS driver 45, a level shift circuit 12, and a pre-driver 13. In this case, the MOS driver 45 is composed of a high-side transistor 10, a parasitic diode 26 between the back gate and the drain which is a parasitic element of the high-side transistor 10, a low-side transistor 11, a parasitic diode 27 between the back gate and the drain which is a parasitic element of the low-side transistor 11, and a pad 8. Moreover, the high-side transistor 10 is connected to a pad 4 for a high voltage power source. The low-side transistor 11 is connected to a pad 5 for a reference potential. The pre-driver 13 is connected to an input terminal 24. Note that, the high-side transistor 10 is used for high level outputting, and the low-side transistor 11 is used for low level outputting.

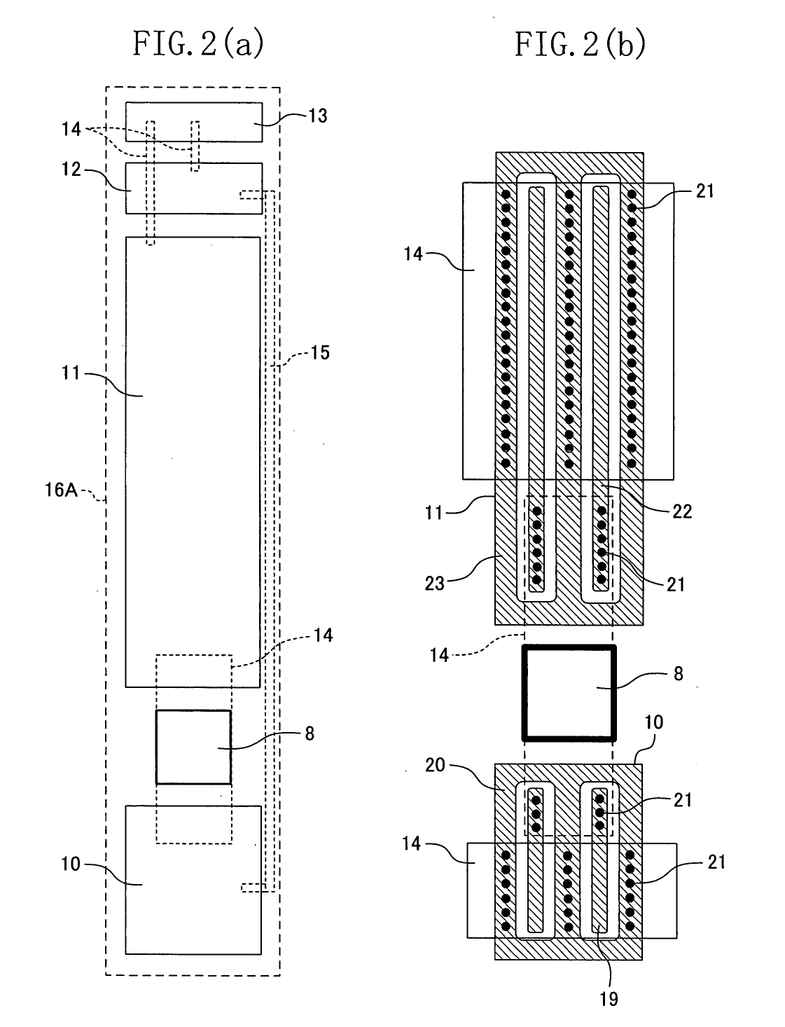

FIG. 2A and FIG. 2B are plan views illustrating a layout in an output circuit cell 16A constituting the output circuit 25a.

As shown in FIG. 2A and FIG. 2B, according to the layout in the output circuit cell 16A, the high-side transistor 10 and the low-side transistor 11 are arranged to face each other with the pad 8 interposed therebetween. The high-side transistor 10 is arranged on one side and the low-side transistor 11 is arranged on the other side with the pad 8 interposed therebetween. The high-side transistor 10 includes the parasitic diode 26 between the back gate and the drain. The parasitic diode 26 serves as an ESD protection element. The low-side transistor 11 includes the parasitic diode 27 between the back gate and the drain. According to this layout, it is possible to improve the resistance against the electrostatic breakdown which occurs when an abnormal input, such as a surge voltage is applied to the pad 8 compared to the conventional example where a pad is arranged at one end, and a low-side transistor and a high-side transistor are arranged in this order over the pad from the bottom (lower side in the drawings; which also applies to the description below) to the top (upper side in the drawings; which also applies to the description below).

Specifically, as shown in FIG. 2A and FIG. 2B, the high-side transistor 10 is arranged at the bottom and the low-side transistor 11, the level shift circuit 12 and the pre-driver 13 are arranged in this order from bottom to top over the pad 8 interposed between the high-side transistor 10 and the low-side transistor 11.

In this layout, a current caused by a minus surge being equal to or lower than the reference potential flows to a body diode of the low-side transistor 11 closest to the pad 8, while a current caused by a plus surge exceeding the power source voltage flows to a body diode of the high-side transistor 10 closest to the pad 8. Therefore, it is possible to improve the resistance against the electrostatic breakdown.

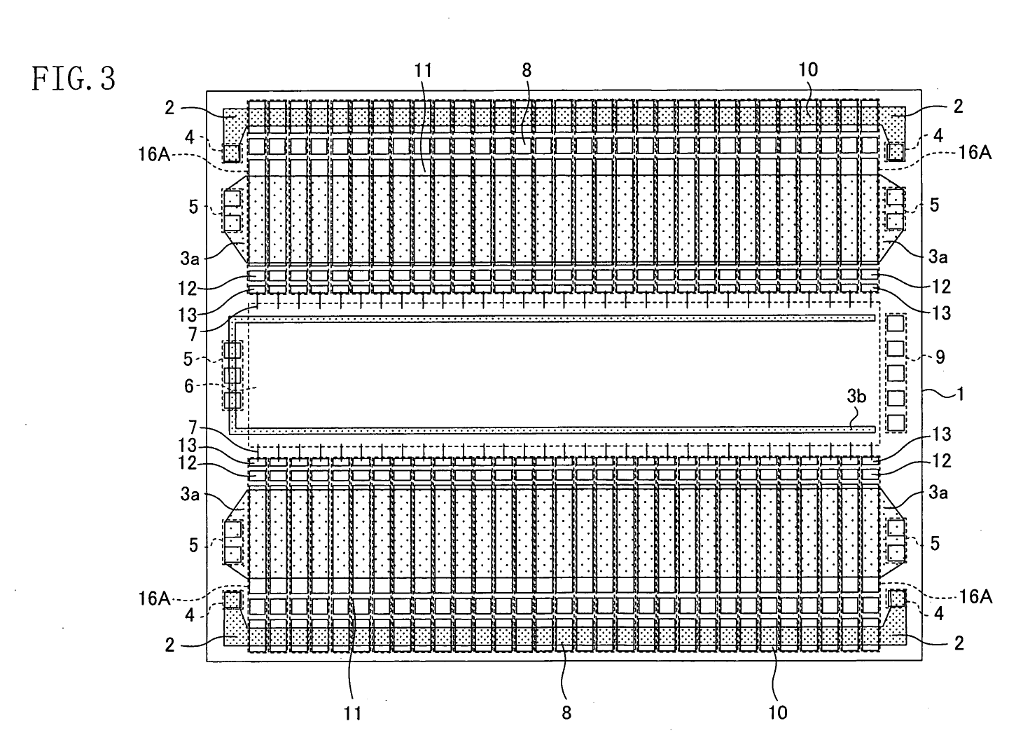

Moreover, as shown in FIG. 2A and FIG. 2B, the high-side transistor 10, the pad 8, the low-side transistor 11, the level shift circuit 12, and the pre-driver 13 are arranged in alignment with each other along a straight line. Therefore, as it is obvious from a layout of a semiconductor integrated circuit shown in FIG. 3 which will be described later, it is possible to realize high integration of the output-circuit cell 16A constituting the output circuit 25a which includes the MOS driver 45. Moreover, the high integration of the semiconductor integrated circuit is realized by designing the cell width of each of the level shift circuit 12 and the pre-driver 13 to be smaller than or equal to that of the low-side transistor 11 which has the largest cell width, specifically, by designing such that the cell width of each of the level shift circuit 12 and the cell width of the pre-driver 13 corresponds to that of the low-side transistor 11 as shown in FIG. 2A and FIG. 2B.

In FIG. 2B, a source region 20 of the high-side transistor 10, a drain region 19 of the high-side transistor 10, through holes 21, a drain region 22 of the low-side transistor 11, and a source region 23 of the low-side transistor 11 are shown.

FIG. 3 is a plan view illustrating a multi-channel semiconductor integrated circuit in which a plurality of output circuit cells 16A each having the above-mentioned layout is arranged on a semiconductor chip 1.

As shown in FIG. 3, a low breakdown voltage control portion 6 is arranged in a center section of the semiconductor chip 1. The low breakdown voltage control portion 6 controls output timing by an input control circuit or the like. Moreover, on the semiconductor chip 1, the plurality of output circuit cells 16A is arranged along sides of the chip to face each other with the low breakdown voltage control portion 6 interposed therebetween. The low breakdown voltage control portion 6 is connected to each of the output circuit cells 16A via a bus line 7. A control signal from the low breakdown voltage control portion 6 is transmitted to each of the pre-drivers 13 via the bus line 7. Moreover, the pads 4 for the high voltage power source are arranged on both sides of the plurality of output circuit cells 16A, and the pads 5 for the reference potential are arranged on both sides of the plurality of output circuit cells 16A. Note that, the layout of the plurality of the output circuit cells 16A is not limited to the layout shown in FIG. 3. Various layouts including such a layout in which bonding wires connected to the pad 8 are not in contact with each other are possible.

Moreover, over the low-side transistors 11 in the output circuit cells 16A, a line 3a to which the reference potential is applied is formed. The line 3a is connected to the pads 5 for the reference potential arranged on the both sides of the plurality of output circuit cells 16A. In the same manner, over the high-side transistors 10 in the output circuit cells 16A, a line 2 to which the high voltage potential is applied is formed. The line 2 to which the high voltage potential is applied is connected to the pads 4 for the high voltage power source, the pads 4 being arranged on the both sides of the plurality of output circuit cells 16A.

Moreover, wires are respectively bonded from a package to the pads 5 for the reference voltage and to the pads 4 for the high voltage power source, each of the pads 5 and the pads 4 being arranged on the both sides of the plurality of output circuit cells 16A in the semiconductor chip 1. Therefore, potentials of the pads 5 for the reference voltage and the pads 4 for the high voltage power source are stable. Therefore, it is possible to reduce line impedance of each of the line 3a to which the reference potential is applied and the line 2 to which the high voltage potential is applied. Moreover, even in a case where a large current is output from each of channels, the reference potential and the high voltage potential of each of the output circuit cells 16A are stable, which makes it possible to obtain uniform output characteristics and ESD resistance. Meanwhile, an input control pad 9 is arranged on one end side in a length direction of the low breakdown control portion 6, and the pad 5 for the reference potential is arranged on the other end side. Moreover, over the low breakdown voltage control portion 6, a line 3b to which the reference potential is applied is arranged so as to surround three sides excepting the side where the input control pad 9 is arranged. The line 3b to which the reference potential is applied serves as a shield which prevents an outer noise input from the pad 8 from being transmitted to the low breakdown voltage control portion 6 via each of the output control cells 16A. Therefore, a signal input from the low breakdown voltage control portion 6 to each of the pre-drivers 13 is stabilized, which stabilizes output characteristics.

### Embodiment 2

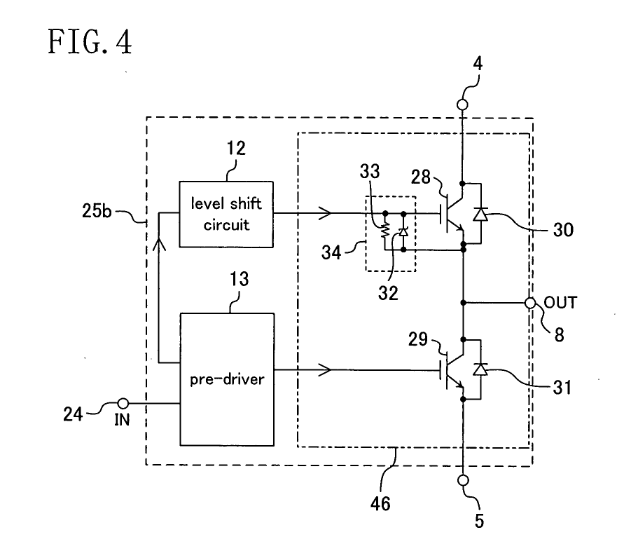

FIG. 4 shows an example of a basic circuit configuration of an output circuit 25b including an output circuit cell of a multi-channel semiconductor integrated circuit of Embodiment 2 of the present invention.

As shown in FIG. 1, the output circuit 25b includes an IGBT driver 46, a level shift circuit 12, and a pre-driver 13. The IGBT driver 46 is composed of a high-side transistor 28, a gate protection circuit 34, a high-side regenerative diode 30, a low-side transistor 29, a low-side regenerative diode 31, and a pad 8. The gate protection circuit 34 includes a gate-off resister 33 and a diode 32 which is used for gate protection. Moreover, the high-side transistor 28 is connected to a pad 4 for a high voltage power source. The low-side transistor 29 is connected to a pad 5 for a reference potential. The pre-driver 13 is connected to an input terminal 24.

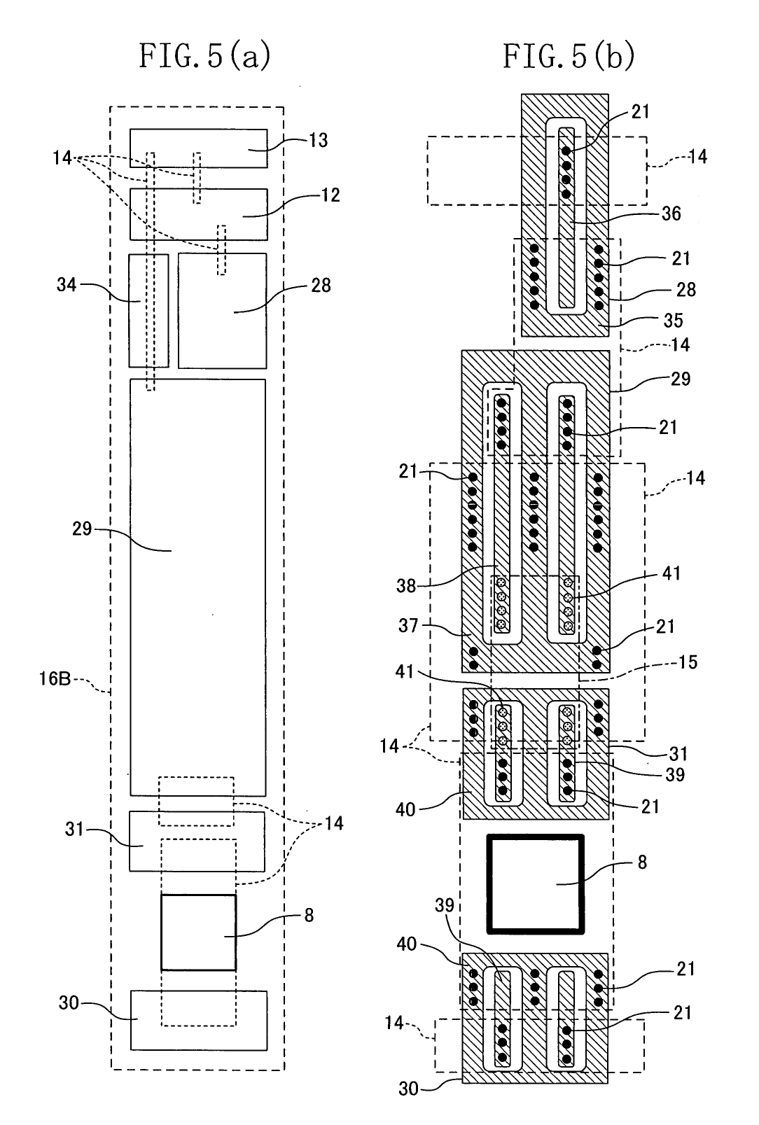

FIG. 5A and FIG. 5B are plan views illustrating a layout of an output circuit cell 16B constituting the output circuit 25b.

As shown in FIG. 5A and FIG. 5B, according to the layout in the output circuit cell 16B, the high-side regenerative diode 30 and the low-side regenerative diode 31 are arranged to face each other with the pad 8 interposed therebetween. The high-side regenerative diode 30 is arranged on one side and the low-side regenerative diode 31 is arranged on the other side with the pad 8 interposed therebetween. The high-side regenerative diode 30 serves as an ESD protection element. According to this layout, it is possible to improve the resistance against the electrostatic breakdown which occurs when an abnormal input, such as a surge voltage is applied to the pad 8 compared to the conventional example where a pad is arranged at one end, and the low-side regenerative diode and a high-side regenerative diode are arranged in this order over the pad from the bottom to the top.

Specifically, as shown in FIG. 5A and FIG. 5B, the high-side regenerative diode 30 is arranged at the bottom, and the low-side regenerative diode 31, the low-side transistor 29, the high-side transistor 28, the gate protection circuit 34, the level shift circuit 12 and the pre-driver 13 are arranged in this order from bottom to top over the pad 8 interposed between the high-side regenerative diode 30 and the low-side regenerative diode 31.

In this layout, a current caused by a minus surge being equal to or lower than the reference potential flows to the low-side regenerative diode 31 closest to the pad 8, while a current caused by a plus surge exceeding the power source voltage flows to the high-side regenerative diode 30 closest to the pad 8. Therefore, it is possible to improve the resistance against the electrostatic breakdown.

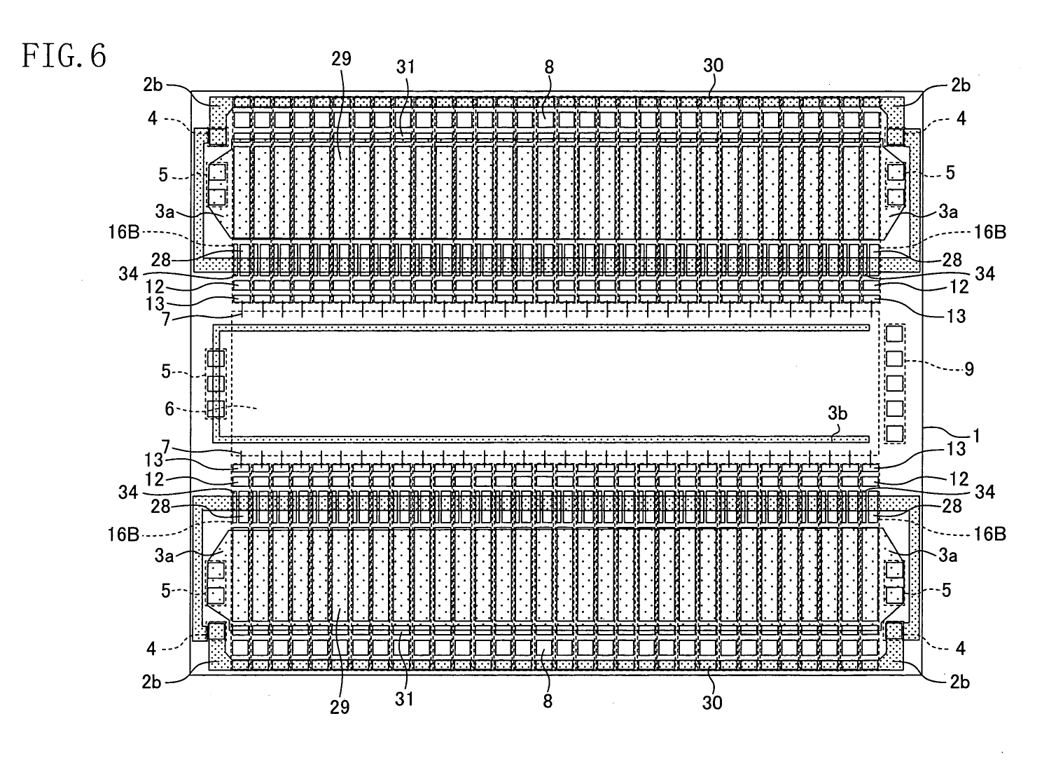

Moreover, as shown in FIG. 5A and FIG. 5B, the high-side regenerative diode 30, the pad 8, the low-side regenerative diode 31, the low-side transistor 29, the high-side transistor 28, the gate protection circuit 34, the level shift circuit 12, and the pre-driver 13 are arranged in alignment with each other along a straight line. Therefore, as it is obvious from a layout of a semiconductor integrated circuit shown in FIG. 6 which will be described later, it is possible to realize high integration of the output circuit cell 16B constituting the output circuit 25b which includes the IGBT driver 46. Moreover, the high integration of the semiconductor integrated circuit is realized by designing the cell width of each of the level shift circuit 12 and the pre-driver 13 to be smaller than or equal to that of the low-side transistor 29 which has the largest cell width, specifically, by designing such that the cell width of each of the level shift circuit 12 and the cell width of the pre-driver 13 corresponds to that of the low-side transistor 29 as shown in FIG. 5A and FIG. 5B.

In FIG. 5B, through holes 21, contacts 41, a corrector region 36 of the high-side transistor 28, an emitter region 35 of the high-side transistor 28, an emitter region 37 of the low-side transistor 29, a corrector region 38 of the low-side transistor 29, a cathode region 39 of the low-side regenerative diode 31 and the high-side regenerative diode 30, and an anode region 40 of the low-side regenerative diode 31 and the high-side regenerative diode 30 are shown.

FIG. 6 is a plan view illustrating a multi-channel semiconductor integrated circuit in which a plurality of output circuit cells 16B each having the above-mentioned layout is arranged on the semiconductor chip 1.

As shown in FIG. 6, a low breakdown voltage control portion 6 is arranged in a center section of the semiconductor chip 1. The low breakdown voltage control portion 6 controls output timing by an input control circuit or the like. Moreover, on the semiconductor chip 1, the plurality of output circuit cells 16B is arranged along sides of the chip to face each other with the low breakdown voltage control portion 6 interposed therebetween. The low breakdown voltage control portion 6 is connected to each of the output circuit cells 16B via a bus line 7. A control signal from the low breakdown voltage control portion 6 is transmitted to each of the pre-drivers 13 via the bus line 7. Moreover, the pads 4 for the high voltage power source are arranged on both sides of the plurality of output circuit cells 16B, and the pads 5 for the reference potential are arranged on both sides of the plurality of output circuit cells 16B. Note that, the layout of the plurality of the output circuit cells 16B is not limited to the layout shown in FIG. 6. Various layouts including such a layout in which bonding wires connected to the pad 8 are not in contact with each other are possible.

Moreover, over the low-side transistors 29 in the output circuit cells 16B, a line 3a to which the reference potential is applied is formed. The line 3a is connected to the pads 5 for the reference potential arranged on the both sides of the plurality of output circuit cells 16B. In the same manner, over the high-side regenerative diodes 30 in the output circuit cells 16B, a line 2b to which the high voltage potential is applied is formed. The line 2b to which the high voltage potential is applied is connected to the pads 4 for the high voltage power source, the pads 4 being arranged on the both sides of the plurality of output circuit cells 16B.

Moreover, wires are respectively bonded from a package to the pads 5 for the reference voltage and to the pads 4 for the high voltage power source, each of the pads 5 and the pads 4 being arranged on the both sides of the plurality of output circuit cells 16B in the semiconductor chip 1. Therefore, potentials of the pads 5 for the reference voltage and the pads 4 for the high voltage power source are stable. Therefore, even in a case where a large current is output from each of channels, the reference potential and the high voltage potential of each of the output circuit cells 16B are stable, which makes it possible to obtain uniform output characteristics and ESD resistance. Meanwhile, an input control pad 9 is arranged on one end side in a length direction of the low breakdown control portion 6, and the pad 5 for the reference potential is arranged on the other end side. Moreover, over the low breakdown voltage control portion 6, a line 3b to which the reference potential is applied is arranged so as to surround three sides excepting the side where the input control pad 9 is arranged. The line 3b to which the reference potential is applied serves as a shield which prevents an outer noise input from the pad 8 from being transmitted to the low breakdown voltage control portion 6 via each of the output control cells 16B. Therefore, a signal input from the low breakdown voltage control portion 6 to each of the pre-drivers 13 is stabilized, which stabilizes output characteristics.

### Embodiment 3

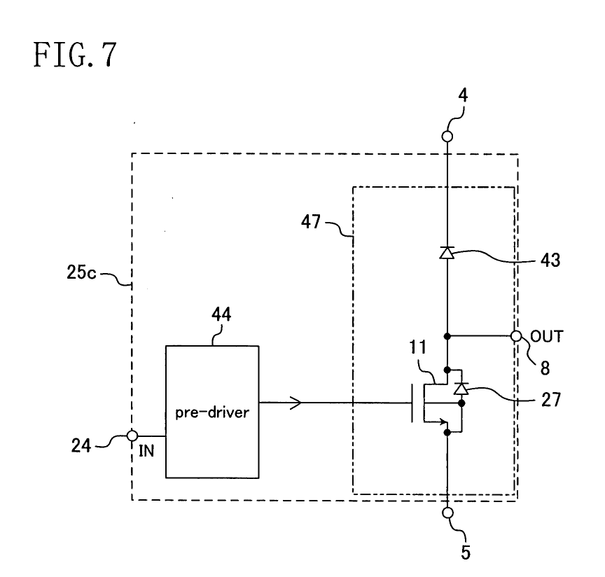

FIG. 7 shows an example of a basic circuit configuration of an output circuit 25c including an output circuit cell of a multi-channel semiconductor integrated circuit of Embodiment 3 of the present invention.

As shown in FIG. 7, the output circuit 25c includes a high-sideless MOS driver 47 and a pre-driver 44. The high-sideless MOS driver 47 is composed of a low-side transistor 11, a parasitic diode 27 between the back gate and the drain which is a parasitic element of the low-side transistor 11, an ESD protection element 43, and a pad 8. Moreover, one end of the low-side transistor 11 is connected to a pad 4 for a high voltage power source. The other end of the low-side transistor 11 is connected to a pad 5 for a reference potential. The pre-driver 44 is connected to an input terminal 24.

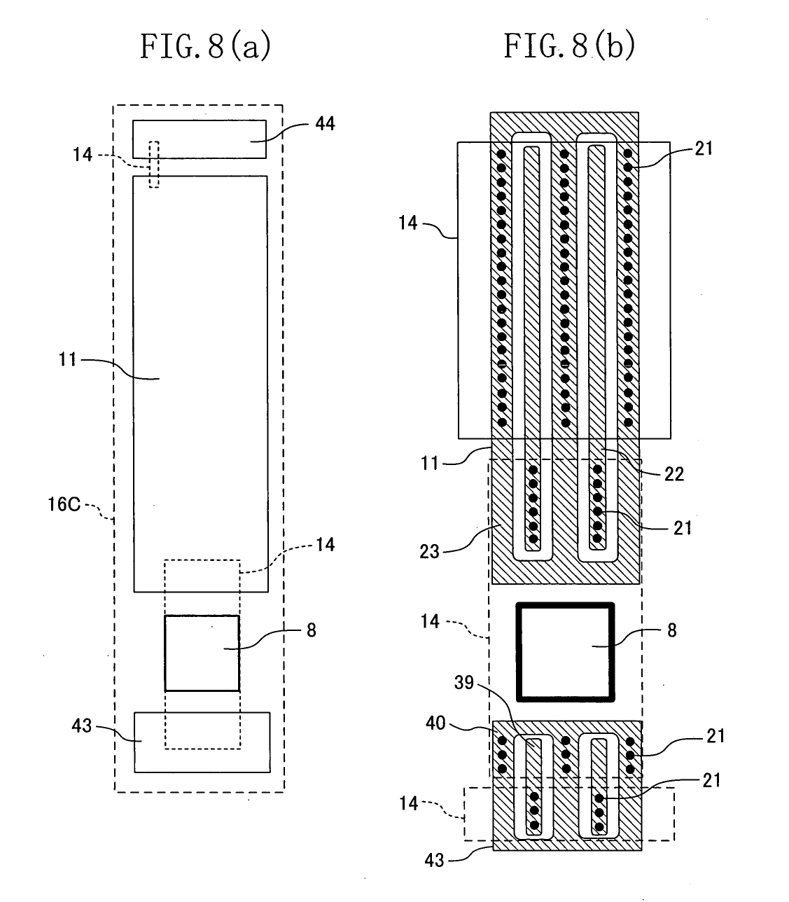

FIG. 8A and FIG. 8B are plan views illustrating a layout in an output circuit cell 16C constituting the output circuit 25c.

As shown in FIG. 8A and FIG. 8B, according to the layout in the output circuit cell 16C, the ESD protection element 43 and the low-side transistor 11 are arranged to face each other with the pad 8 interposed therebetween. The ESD protection element 43 is arranged on one side and the low-side transistor 11 is arranged on the other side with the pad 8 interposed therebetween. According to this layout, it is possible to improve the resistance against the electrostatic breakdown which occurs when an abnormal input, such as a surge voltage is applied to the pad 8 compared to the conventional example where a pad is arranged at one end, and the low-side transistor 11 and the ESD protection element are arranged in this order over the pad from the bottom to the top.

Specifically, as shown in FIG. 8A and FIG. 8B, the ESD protection element 43 is arranged at the bottom, and the low-side transistor 11 and the pre-driver 44 are arranged in this order from bottom to top over the pad 8 interposed between the ESD protection element 43 and the low-side transistor 11.

In this layout, a current caused by a minus surge being equal to or lower than the reference potential flows to the body diode of the low-side transistor 11 closest to the pad 8, while a current caused by a plus surge exceeding the power source voltage flows to the ESD protection element 43 closest to the pad 8. Therefore, it is possible to improve the resistance against the electrostatic breakdown.

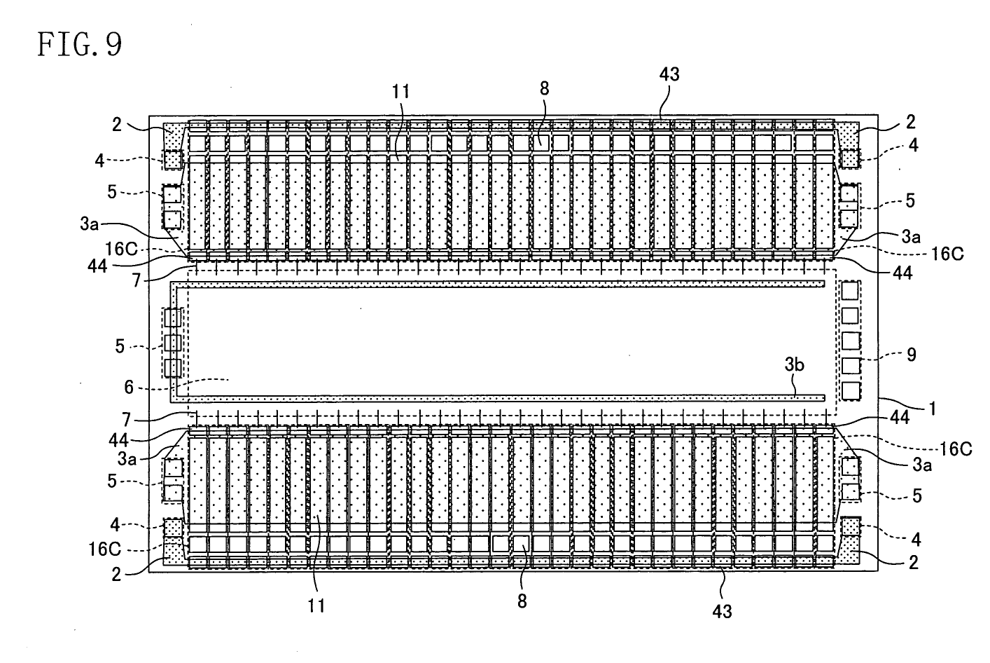

Moreover, as shown in FIG. 8A and FIG. 8B, the ESD protection element 43, the pad 8, the low-side transistor 11, and the pre-driver 44 are arranged in alignment with each other along a straight line. Therefore, as it is obvious from a layout of a semiconductor integrated circuit shown in FIG. 9 which will be described later, it is possible to realize high integration of the output circuit cell 16C constituting the output circuit 25c which includes the high-sideless MOS driver 47. Moreover, the high integration of the semiconductor integrated circuit is realized by designing the cell width of the pre-driver 44 to be smaller than or equal to that of the low-side transistor 11 which has the largest cell width, specifically, by designing such that the cell width of the pre-driver 44 corresponds to that of the low-side transistor 11 as shown in FIG. 8A and FIG. 8B.

In FIG. 8B, through holes 21, a drain region 22 of the low-side transistor 11, a source region 23 of the low-side transistor 11, a cathode region 39 of the ESD protection element 43, and an anode region of the ESD protection element 43 are shown.

FIG. 9 is a plan view illustrating a multi-channel semiconductor integrated circuit in which a plurality of output circuit cells 16C each having the above-mentioned layout is arranged on a semiconductor chip 1.

As shown in FIG. 9, a low breakdown voltage control portion 6 is arranged in a center section of the semiconductor chip 1. The low breakdown voltage control portion 6 controls output timing by an input control circuit or the like. Moreover, on the semiconductor chip 1, the plurality of output circuit cells 16C is arranged along sides of the chip to face each other with the low breakdown voltage control portion 6 interposed therebetween. The low breakdown voltage control portion 6 is connected to each of the output circuit cells 16C via a bus line 7. A control signal from the low breakdown voltage control portion 6 is transmitted to each of the pre-drivers 44 via the bus line 7. Moreover, the pads 4 for the high voltage power source are arranged on both sides of the plurality of output circuit cells 16C, and the pads 5 for the reference potential are arranged on both sides of the plurality of output circuit cells 16C. Note that, the layout of the plurality of the output circuit cells 16C is not limited to the layout shown in FIG. 9. Various layouts including such a layout in which bonding wires connected to the pad 8 are not in contact with each other are possible.

Moreover, over the low-side transistors 11 in the output circuit cells 16C, a line 3a to which the reference potential is applied is formed. The line 3a is connected to the pads 5 for the reference potential arranged on the both sides of the plurality of output circuit cells 16C. In the same manner, over the ESD protection elements 43 in the output circuit cells 16C, a line 2 to which the high voltage potential is applied is formed. The line 2 to which the high voltage potential is applied is connected to the pads 4 for the high voltage power source, the pads 4 being arranged on the both sides of the plurality of output circuit cells 16C.

Moreover, wires are respectively bonded from a package to the pads 5 for the reference voltage and to the pads 4 for the high voltage power source, each of the pads 5 and the pads 4 being arranged on the both sides of the plurality of output circuit cells 16C in the semiconductor chip 1. Therefore, potentials of the pads 5 for the reference voltage and the pads 4 for the high voltage power source are stable. Therefore, even in a case where a large current is output from each of channels, the reference potential and the high voltage potential of each of the output circuit cells 16C are stable, which makes it possible to obtain uniform output characteristics and ESD resistance. Meanwhile, an input control pad 9 is arranged on one end side in a length direction of the low breakdown control portion 6, and the pad 5 for the reference potential is arranged on the other end side. Moreover, over the low breakdown voltage control portion 6, a line 3b to which the reference potential is applied is arranged so as to surround three sides excepting the side where the input control pad 9 is arranged. The line 3b to which the reference potential is applied serves as a shield which prevents an outer noise input from the pad 8 from being transmitted to the low breakdown voltage control portion 6 via each of the output control cells 16C. Therefore, a signal input from the low breakdown voltage control portion 6 to each of the pre-drivers 44 is stabilized, which stabilizes output characteristics.

### Embodiment 4

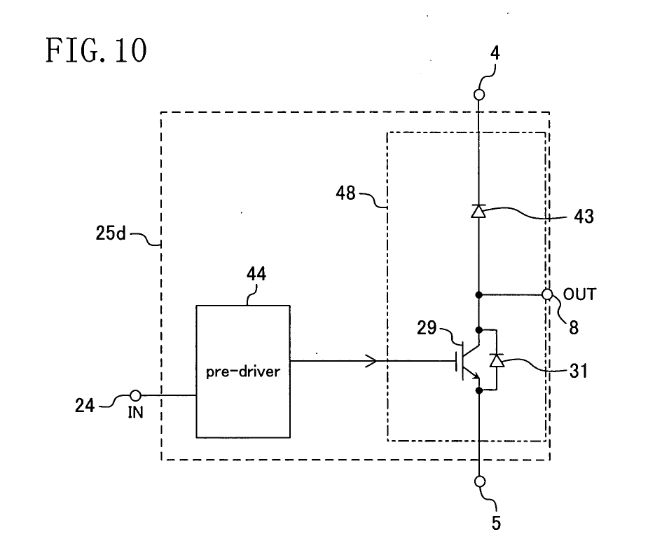

FIG. 10 shows an example of a basic circuit configuration of an output circuit 25d including an output circuit cell of a multi-channel semiconductor integrated circuit of Embodiment 4 of the present invention.

As shown in FIG. 10, the output circuit 25d includes a high-sideless IGBT driver 48 and a pre-driver 44. The high-sideless IGBT driver 86 is composed of a low-side transistor 29, a low-side regenerative diode 31, an ESD protection element 43, and a pad 8. Moreover, one end of the low-side transistor 29 is connected to a pad 4 for a high voltage power source. The other end of the low-side transistor 29 is connected to a pad 5 for a reference potential. The pre-driver 44 is connected to an input terminal 24.

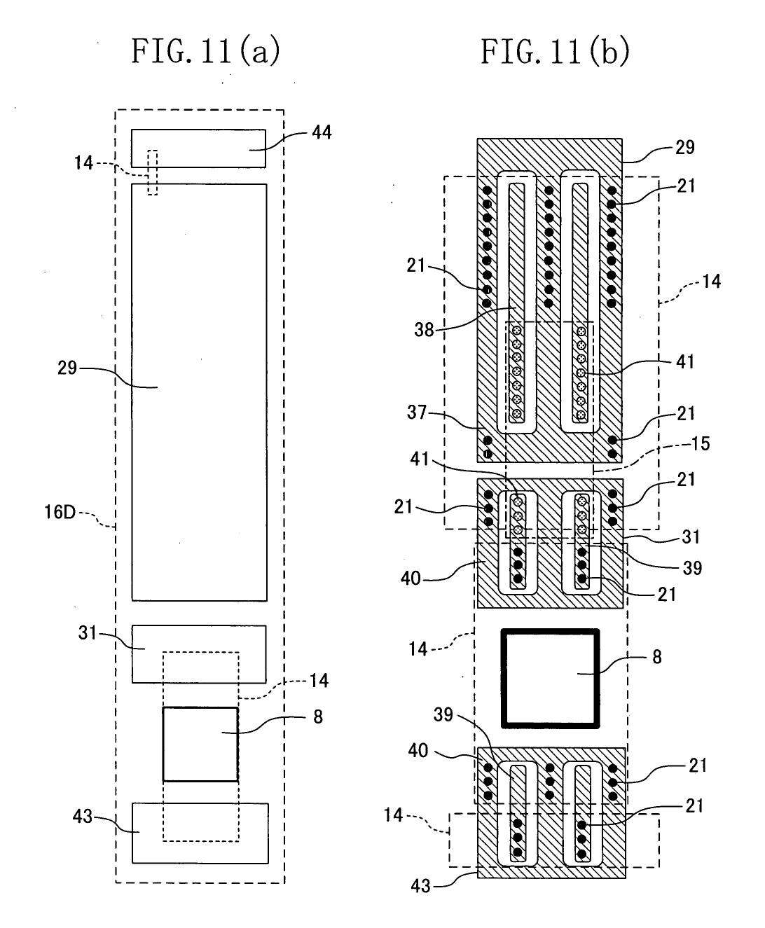

FIG. 11A and FIG. 11B are plan views illustrating a layout in an output circuit cell 16D constituting the output circuit 25d.

As shown in FIG. 11A and FIG. 11B, according to the layout in the output circuit cell 16D, the ESD protection element 43 and the low-side regenerative diode 31 are arranged to face each other with the pad 8 interposed therebetween. The ESD protection element 43 is arranged on one side and the low-side regenerative diode 31 is arranged on the other side with the pad 8 interposed therebetween. According to this layout, it is possible to improve the resistance against the electrostatic breakdown which occurs when an abnormal input, such as a surge voltage is applied to the pad 8 compared to the conventional example where a pad is arranged at one end, and the low-side regenerative diode 31 and the ESD protection element 43 are arranged in this order over the pad from the bottom to the top.

Specifically, as shown in FIG. 11A and FIG. 11B, the ESD protection element 43 is arranged at the bottom, and the low-side regenerative diode 31, the low-side transistor 29 and the pre-driver 44 are arranged in this order from bottom to top over the pad 8 interposed between the ESD protection element 43 and the low-side regenerative diode 31.

In this layout, a current caused by a minus surge being equal to or lower than the reference potential flows to the low-side regenerative diode 31 closest to the pad 8, while a current caused by a plus surge exceeding the power source voltage flows to the ESD protection element 43 closest to the pad 8. Therefore, it is possible to improve the resistance against the electrostatic breakdown.

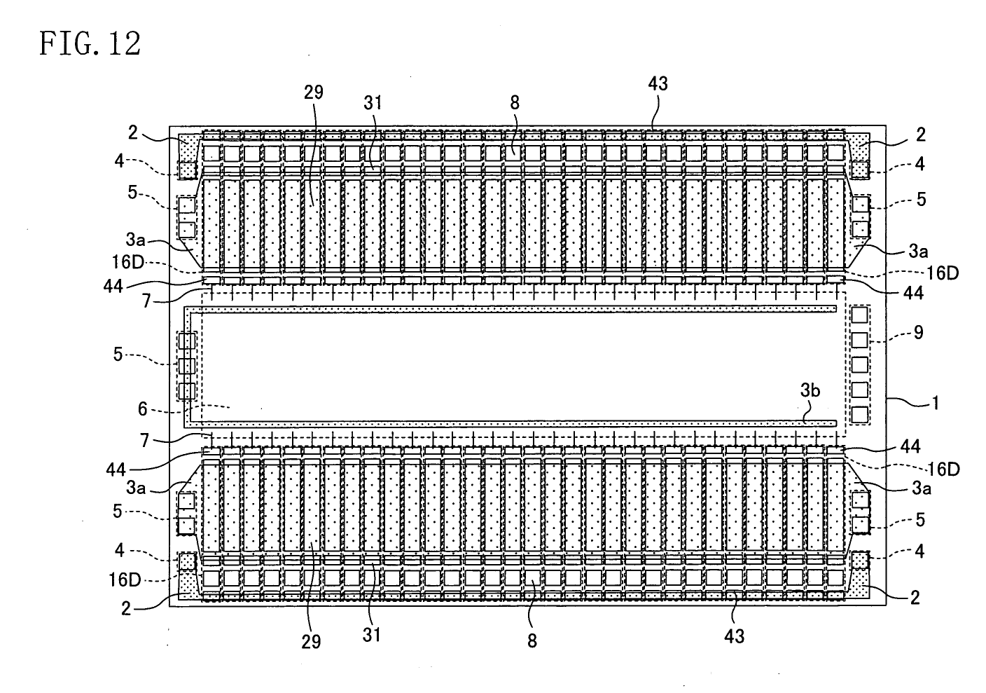

Moreover, as shown in FIG. 11A and FIG. 11B, the ESD protection element 43, the pad 8, the low-side regenerative diode 31, the low-side transistor 29, and the pre-driver 44 are arranged in alignment with each other along a straight line. Therefore, as it is obvious from a layout of a semiconductor integrated circuit shown in FIG. 12 which will be described later, it is possible to realize high integration of the output circuit cell 16D constituting the output circuit 25d which includes the high-sideless IGBT driver 48. Moreover, the high integration of the semiconductor integrated circuit is realized by designing the cell width of the pre-driver 44 to be smaller than or equal to that of the low-side transistor 29 which has the largest cell width, specifically, by designing such that the cell width of the pre-driver 44 corresponds to that of the low-side transistor 29 as shown in FIG. 11A and FIG. 11B.

In FIG. 11B, through holes 21, contacts 41, an emitter region 37 of the low-side transistor 29, a corrector region 38 of the low-side transistor 29, a cathode region 39 of the low-side diode 31 and the ESD protection element 43, and an anode region 40 of the low-side diode 31 and the ESD protection element 43 are shown.

FIG. 12 is a plan view illustrating a multi-channel semiconductor integrated circuit in which a plurality of output circuit cells 16D each having the above-mentioned layout is arranged on a semiconductor chip 1.

As shown in FIG. 12, a low breakdown voltage control portion 6 is arranged in a center section of the semiconductor chip 1. The low breakdown voltage control portion 6 controls output timing by an input control circuit or the like. Moreover, on the semiconductor chip 1, the plurality of output circuit cells 16D is arranged along sides of the chip to face each other with the low breakdown voltage control portion 6 interposed therebetween. The low breakdown voltage control portion 6 is connected to each of the output circuit cells 16D via a bus line 7. A control signal from the low breakdown voltage control portion 6 is transmitted to each of the pre-drivers 44 via the bus line 7. Moreover, the pads 4 for the high voltage power source are arranged on both sides of the plurality of output circuit cells 16D, and the pads 5 for the reference potential are arranged on both sides of the plurality of output circuit cells 16D. Note that, the layout of the plurality of the output circuit cells 16D is not limited to the layout shown in FIG. 12. Various layouts including such a layout in which bonding wires connected to the pad 8 are not in contact with each other are possible.

Moreover, over the low-side transistors 29 in the output circuit cells 16D, a line 3a to which the reference potential is applied is formed. The line 3a is connected to the pads 5 for the reference potential arranged on the both sides of the plurality of output circuit cells 16D. In the same manner, over the ESD protection elements 43 in the output circuit cells 16D, a line 2 to which the high voltage potential is applied is formed. The line 2 to which the high voltage potential is applied is connected to the pads 4 for the high voltage power source, the pads 4 being arranged on the both sides of the plurality of output circuit cells 16D.

Moreover, wires are respectively bonded from a package to the pads 5 for the reference voltage and to the pads 4 for the high voltage power source, each of the pads 5 and the pads 4 being arranged on the both sides of the plurality of output circuit cells 16D in the semiconductor chip 1. Therefore, potentials of the pads 5 for the reference voltage and the pads 4 for the high voltage power source are stable. Therefore, even in a case where a large current is output from each of channels, the reference potential and the high voltage potential of each of the output circuit cells 16D are stable, which makes it possible to obtain uniform output characteristics and ESD resistance. Meanwhile, an input control pad 9 is arranged on one end side in a length direction of the low breakdown control portion 6, and the pad 5 for the reference potential is arranged on the other end side. Moreover, over the low breakdown voltage control portion 6, a line 3b to which the reference potential is applied is arranged so as to surround three sides excepting the side where the input control pad 9 is arranged. The line 3b to which the reference potential is applied serves as a shield which prevents an outer noise input from the pad 8 from being transmitted to the low breakdown voltage control portion 6 via each of the output control cells 16D. Therefore, a signal input from the low breakdown voltage control portion 6 to each of the pre-drivers 44 is stabilized, which stabilizes output characteristics.

Note that, in the Embodiments above, the term “reference potential” is used to include not only ground potentials but also potentials other than the ground potential. However, the term “reference potential” indicates a potential applied to a substrate of a semiconductor chip and usually means ground potential.

### INDUSTRIAL APPLICABILITY

The present invention is applicable to a multi-channel semiconductor integrated circuit which drives a capacitive load, for example, PDP.

1. A semiconductor integrated circuit including a plurality of circuit cells each having a pad on a semiconductor chip,
each of the circuit cells comprising:
a first diode structure;
a second diode structure; and
the pad between the first diode structure and the second diode structure,
wherein an anode section of the first diode structure and a cathode section of the second diode structure are connected to the pad.

2-24. (canceled)

25. The semiconductor integrated circuit of claim 1, wherein
each of the first diode structure and the second diode structure is a parasitic diode.

26. The semiconductor integrated circuit of claim 1, wherein
each of the first diode structure and the second diode structure is a diode element.

27. The semiconductor integrated circuit of claim 1, wherein
one of the first diode structure and the second diode structure is a parasitic diode, and the other is a diode element.

28. The semiconductor integrated circuit of claim 25, wherein
each of the circuit cells further comprises a high-side transistor and a low-side transistor,
the first diode structure is the parasitic diode of the high-side transistor, and
the second diode structure is the parasitic diode of the low-side transistor.

29. The semiconductor integrated circuit of claim 28, wherein
the parasitic diode of the high-side transistor is a body diode of the high-side transistor, and
the parasitic diode of the low-side transistor is a body diode of the low-side transistor.

30. A semiconductor integrated circuit of claim 26, wherein
each of the circuit cells further comprises a high-side transistor, a high-side regenerative diode, a low-side transistor, and a low-side regenerative diode,
the first diode structure is the high-side regenerative diode, and
the second diode structure is the low-side regenerative diode.

31. The semiconductor integrated circuit of claim 27, wherein
each of the circuit cells further comprises an ESD protection element and a low-side transistor,
the first diode structure is the ESD protection element, and
the second diode structure is the parasitic diode of the low-side transistor.

32. The semiconductor integrated circuit of claim 26, wherein
each of the circuit cells further comprises an ESD protection element, a low-side regenerative diode, and a low-side transistor,
the first diode structure is the ESD protection element, and
the second diode structure is the low-side regenerative diode.

33. The semiconductor integrated circuit of claim 1, further comprising:
a control portion arranged in a center section of the semiconductor chip;
a first circuit cell alignment of the plurality of circuit cells; and
a second circuit cell alignment of the plurality of circuit cells,
wherein the first circuit cell alignment and the second cell alignment face each other with the control portion interposed therebetween.

34. The semiconductor integrated circuit of claim 28, wherein
each of the circuit cells comprises:
a high breakdown voltage driver composed of the high-side transistor, a level shift circuit driving the high-side transistor, and the low-side transistor;
a pre-driver driving the high breakdown voltage driver; and
the pad, and
the high-side transistor, the pad, the low-side transistor, the level shift circuit, and the pre-driver are arranged in alignment with each other along a straight line.

35. The semiconductor integrated circuit of claim 30, wherein
each of the circuit cells further comprises:
a high breakdown voltage driver composed of the high-side transistor, a level shift circuit driving the high-side transistor, the high-side regenerative diode, the low-side transistor, and the low-side regenerative diode;
a pre-driver driving the high breakdown voltage driver; and
the pad, and
the high-side regenerative diode, the pad, the low-side regenerative diode, the low-side transistor, the high-side transistor, the level shift circuit, and the pre-driver are arranged in alignment with each other along a straight line.

36. The semiconductor integrated circuit of claim 31, wherein
each of the circuit cells further comprises:
the ESD protection element;
a high breakdown voltage driver composed of the low-side transistor;
a pre-driver driving the high breakdown voltage driver; and
the pad, and
the ESD protection element, the pad, the low-side transistor, and the pre-driver are arranged in alignment with each other along a straight line.

37. The semiconductor integrated circuit of claim 32, wherein
each of the circuit cells further comprises:
the ESD protection element;
a high breakdown voltage driver composed of the low-side regenerative diode and the low-side transistor;
a pre-driver driving the high breakdown voltage driver; and
the pad, and
the ESD protection element, the pad, the low-side regenerative diode, the low-side transistor, and the pre-driver are arranged in alignment with each other along a straight line.

38. The semiconductor integrated circuit of claim 1, further comprising:
first power source pads for a high voltage potential arranged on both ends of the circuit cell alignment of the plurality of circuit cells;
second power source pads for a reference potential arranged on both ends of the circuit cell alignment of the plurality of circuit cells;
a first line to which the high voltage potential is applied, the first line being electrically connected to the first power source pads and being arranged over the first diode structure in each of the circuit cells of the circuit cell alignment; and
a second line to which the reference voltage is applied, the second line being electrically connected to the second power source pads and being arranged over the second diode structure in each of the circuit cells of the circuit cell alignment.

39. The semiconductor integrated circuit of claim 38, further comprising:
a third line to which the reference voltage is applied, the third line surrounding part of a control portion arranged in a center section of the semiconductor chip.
